(19) United States
(12) Patent Application Publication
(10) Pub. No.: US 2011/0008539 A1
(43) Pub. Date: Jan. 13, 2011

(54) VAPOR GENERATOR AND VAPOR DEPOSITION APPARATUS

(75) Inventor: Toshio NEGISHI, Chigasaki-shi (JP)

Correspondence Address: KRATZ, QUINTOS & HANSON, LLP, 1420 K Street, N.W., 4th Floor, WASHINGTON, DC, 20005, US

(73) Assignee: ULVAC,INC., Chigasaki-shi (JP)

(21) Appl. No.: 12/855,349

(22) Filed: Aug. 12, 2010

Related U.S. Application Data
(63) Continuation of application No. PCT/JP2009/052268, filed on Feb. 12, 2009.

(30) Foreign Application Priority Data
Feb. 14, 2008 (JP) 2008-032799

(51) Int. Cl. C23C 16/00

(52) U.S. Cl. 427/248.1; 118/715

(57) ABSTRACT

An organic thin film having excellent film quality is formed. A vapor generator of the present invention has an evaporation chamber, a dispense head and a tank. A vapor deposition material is in the liquid state, stored in the tank, and fed to the dispense head from the tank. The dispense head dispenses the vapor deposition material fed inside thereof from a dispense orifice and disposes the vapor deposition material on a heating member inside the evaporation chamber. The dispense head accurately feeds the vapor deposition material by a required amount. Because only the required amount of the vapor deposition material is heated, an organic thin film excellent in film quality is formed without deterioration.

This application is a continuation of International Application No. PCT/JP2009/052268 filed Feb. 12, 2009, which claims priority to Japanese Patent Document No. 2008-032799, filed on Feb. 14, 2008. The entire disclosures of the prior applications are herein incorporated by reference in their entireties.

### BACKGROUND

The present invention relates to a vapor generator and a vapor deposition apparatus using the same.

An organic EL element is one of the display elements that has most attracted attention in recent years and has excellent properties of high luminance and high-speed response. In an organic EL element, light emission regions that produce three different colors of red, green and blue, are arranged on a glass substrate. The light emission region includes an anode electrode film, a hole injection layer, a hole transport layer, a light emission layer, an electron transport layer, an electron injection layer, and a cathode electrode film stacked in this order; and red, green or blue is produced by a coloring agent added in the light emission layer.

The hole transport layer, the light emission layer, the electron transport layer or the like are configured in general by an organic material; and a vapor deposition apparatus is widely used to form such an organic material film.

Reference numeral 203 in FIG. 4 represents a vapor deposition apparatus of the conventional art, in which a vapor deposition vessel 212 is disposed inside a vacuum chamber. The vapor deposition vessel 212 has a vessel main body 221; and the top part of the vessel main body 221 is covered with a lid member 222 having at least one discharge hole 224 formed therein.

Inside the vapor deposition vessel 212, an organic vapor deposition material 200 in the form of powder is disposed. A heating means 223 is arranged on the side and bottom of the vapor deposition vessel 212; and the vacuum chamber 211 is vacuum evacuated. When the heating means 223 produces heat, the temperature of the vapor deposition vessel 212 is raised and the organic vapor deposition material 200 in the vapor deposition vessel 212 is heated.

When the organic vapor deposition material 200 is heated to its evaporating temperature or higher, the vapor deposition vessel 212 is filled with the vapor of the organic material and the vapor is discharged into the vacuum chamber 211 from the discharge hole 224.

Above the discharge hole 224, a holder 210 is disposed; and when a substrate 205 is held by the holder 210, the organic material vapor discharged from the discharge hole 224 reaches the surface of the substrate 205, and an organic thin film (such as, a hole injection layer, a hole transport layer, and a light emission layer) is formed. If the substrate 205 is caused to pass over the discharge hole 224 one by one while the organic material vapor is discharged, it is possible to form an organic thin film sequentially on a plurality of the substrates 205.

However, in order to form a film on a plurality of the substrates 205, it is necessary to dispose a large amount of organic material in the vapor deposition vessel 212. In an actual production site, film formation processing is performed continuously for 120 hours or more while heating the organic material at 250° C. to 450° C.; and therefore, the organic vapor deposition material 200 in the vapor deposition vessel 212 is exposed to high temperatures for long hours, resulting in transformation due to reaction with water in the vapor deposition vessel 212 and advancement of decomposition due to heating. Consequently, the organic vapor deposition material 200 deteriorates compared to its initial state and the quality of the organic thin film is degraded. Such problems are disclosed in publications, such as, JPA10-140334, JPA2006-307239 and JPA2007-70687.

### SUMMARY OF THE INVENTION

The present invention has been developed to solve the above-mentioned problems; and an object thereof is to form a thin film of high film quality.

In order to solve the above-mentioned problems, the present invention is a vapor generator including an evaporation chamber, and a feeding device that feeds a vapor deposition material into the evaporation chamber, wherein the feeding device has a tank in which a liquid vapor deposition material is disposed and a dispense head connected to the tank, and wherein the dispense head is provided with a dispense orifice, and the vapor deposition material is fed from the tank to the dispense head and dispensed from the dispense orifice to an interior space of the evaporation chamber.

The present invention is a vapor generator having a heating member disposed inside the evaporation chamber and a heating means for heating the heating member, wherein the vapor generator is configured so that the vapor deposition material dispensed from the dispense orifice is disposed on the heating member.

The present invention is a vapor deposition apparatus having the vapor generator discharge device which is connected to the evaporation chamber and to which vapor generated in the evaporation chamber is fed and a vacuum chamber where the vapor is discharged in the interior space of the vacuum chamber from the discharge device.

It is possible to accurately evaporate a necessary amount of vapor deposition material. It is possible to obtain a thin film having high film quality because the vapor deposition material is not heated for long hours; and therefore, it does not deteriorate.

### BRIEF DESCRIPTION OF THE DRAWINGS

FIG. 1 is a plan view for illustrating an example of a manufacturing apparatus of an organic EL element.

FIG. 2 is a schematic sectional view for illustrating an example of a vapor deposition apparatus of the present invention.

FIG. 3 is a sectional view for illustrating a vapor generator of the present invention.

FIG. 4 is a sectional view for illustrating a vapor deposition apparatus of the prior art.

### DETAILED DESCRIPTION OF THE INVENTION

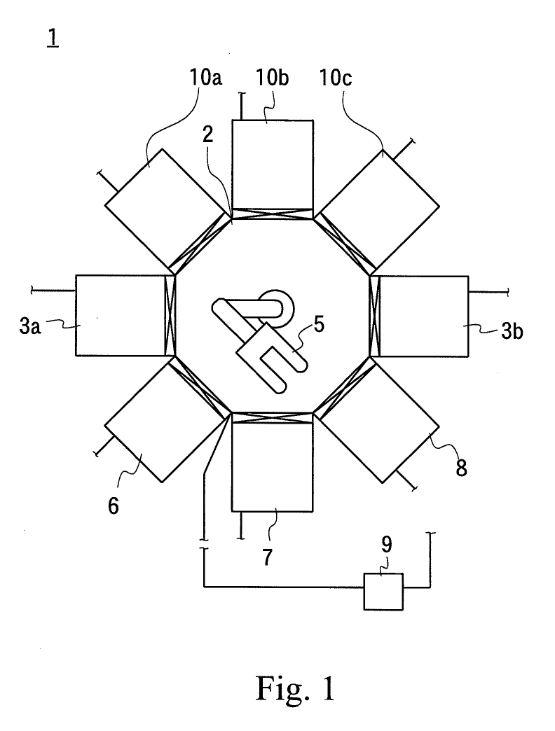

Reference numeral 1 in FIG. 1 generally represents an example of a manufacturing apparatus of the present invention used to manufacture an organic EL element. The manufacturing apparatus 1 has a transfer chamber 2, at least one of vapor deposition apparatuses 10a to 10c, a sputter chamber 7, carry-in/carry-out chambers 3a and 3b, and processing chambers 6 and 8; and each of the vapor deposition apparatuses 10a to 10c, the sputter chamber 7, the carry-in/carry-out chambers 3a and 3b, and the processing chambers 6 and 8 are connected to the transfer chamber 2, respectively.

Each of the vapor deposition apparatuses 10a to 10c, the sputter chamber 7, the carry-in/carry-out chambers 3a and 3b, and each of the processing chambers 6 and 8, a vacuum evacuation system 9 is connected to the transfer chamber 2. The vacuum evacuation system 9 forms a vacuum ambience inside the transfer chamber 2, inside the vapor deposition apparatuses 10a to 10c, inside the processing chambers 6 and 8, inside the sputter chamber 7, inside the carry-in chamber 3a, and inside the carry-out chamber 3b.

Inside the transfer chamber 2, a transfer robot 5 is disposed and a substrate is transferred by the transfer robot 5 in a vacuum ambience, subjected to processing (such as, heating and cleaning) inside the processing chambers 6 and 8; and a transparent conductive film (lower electrode) is formed on the surface of the substrate in the sputter chamber 7; an organic thin film (such as, an electron injection layer, an electron transport layer, a light emission layer, a hole transport layer, and a hole injection layer) is formed by the vapor deposition apparatuses 10a to 10c; an upper electrode is formed on the organic thin film inside the sputter chamber 7; and thus, an organic EL element is obtained. The obtained organic EL element is carried out to the outside from the carry-out chamber 3b.

It may also be possible to manufacture an organic EL element by forming a lower electrode on the surface of the substrate using another manufacturing apparatus in advance before carrying the substrate into the manufacturing apparatus 1 and, if necessary, patterning the lower electrode into a predetermined shape, then carrying the substrate into the manufacturing apparatus 1, and an organic thin films may be formed and an upper electrode on the lower electrode in the order of description.

Next, a vapor deposition apparatus used to form an organic thin film (such as, an electron injection layer, an electron transport layer, a light emission layer, a hole transport layer, and a hole injection layer) is explained.

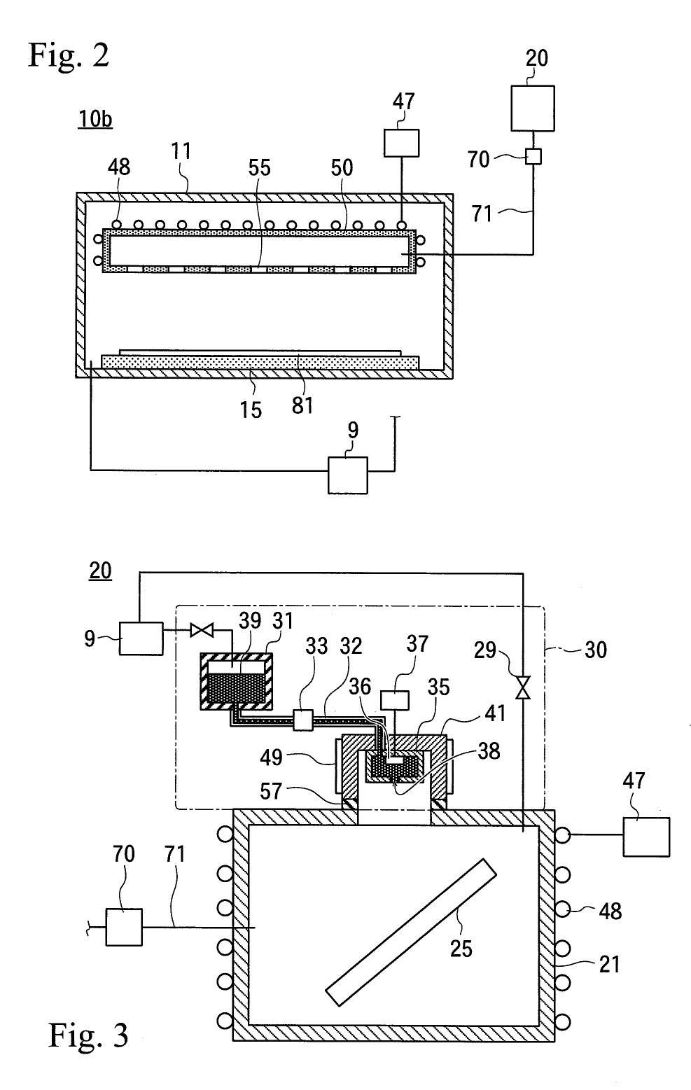

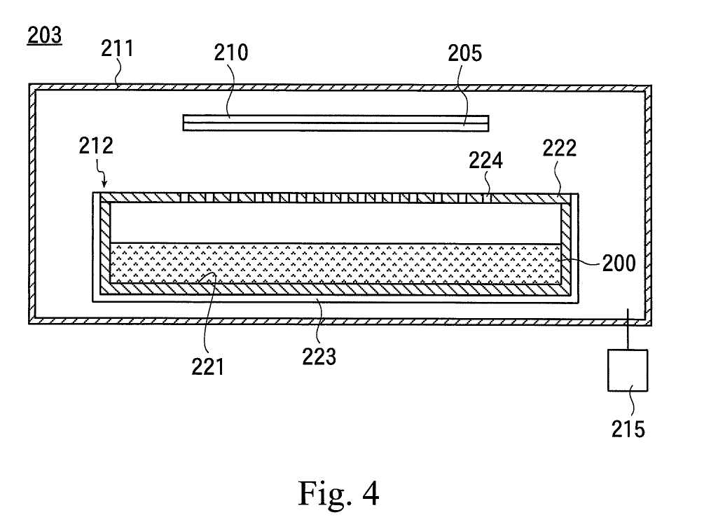

At least one of the vapor deposition apparatuses 10a to 10c in FIG. 1 is configured by the vapor deposition apparatus 10b of the present invention. FIG. 2 is a schematic sectional view of the vapor deposition apparatus 10b of the present invention and the vapor deposition apparatus 10b has a film formation chamber 11 made of a vacuum chamber, a discharge device 50, and at least one vapor generator 20.

At least part of the discharge device 50 is disposed inside the film formation chamber 11 and at least one discharge hole 55 is formed in the part of the discharge device 50 arranged inside the film formation chamber 11. Via the discharge hole 55, the interior space of the film formation chamber 11 and the interior space of the discharge device 50 are connected to each other.

One end of a pipe 71 is connected to each vapor generator 20; and the other end of the pipe 71 is connected to the discharge device 50. Between one end and the other end of each pipe 71, a switching device 70 is provided.

When the switching device 70 is brought into an open state, the vapor generator 20 is connected to the discharge device 50; and when the switching device 70 is brought into a closed state, the vapor generator 20 is shut off from the discharge device 50. When a plurality of vapor generators 20 are provided, the switching devices 70 can be switched between an open state and a closed state, individually; and thereby, each vapor generator 20 can be connected to or shut off from the discharge device 50, individually.

FIG. 3 is a sectional view of the vapor generator 20. The vapor generator 20 has a feeding device 30, an evaporation chamber 21, a heating member 25, and a heating means 48. The heating member 25 is disposed inside the evaporation chamber 21. The heating means 48 is attached to one or both of the evaporation chamber 21 and the heating member 25; and when the heating means 48 is energized by a power source 47, the temperature of the member to which the heating means 48 is not attached is also raised due to radiant heat or thermal conduction, and both the evaporation chamber 21 and the heating member 25 are heated.

The feeding device 30 has a dispense head 35, a tank 31, and a dispense chamber 41.

In the ceiling of the evaporation chamber 21 and in the bottom wall of the dispense chamber 41, an opening is formed, respectively. The dispense chamber 41 is attached to the evaporation chamber 21 in a state such that the opening in the bottom wall of the dispense chamber 41 is communicated with the opening in the ceiling of the evaporation chamber 21 in an airtight manner.

The dispense head 35 has at least one dispense orifice 38. The dispense head 35 is disposed inside the dispense chamber 41 in a state such that the dispense orifice 38 faces the surface of the heating member 25 via the openings communicated with each other. Between the dispense chamber 41 and the evaporation chamber 21, a heat insulating member is disposed; and therefore, it is unlikely to transmit heat to the dispense head 35, and even when the evaporation chamber 21 and the heating member 25 are heated, the temperature of the dispense head 35 does not reach such a high temperature as the temperature of the evaporation chamber 21 and the heating member 25.

The tank 31 is disposed outside of the dispense chamber 41. FIG. 3 shows a state where a liquid vapor deposition material 39 is stored in the tank 31. One end of a feeding pipe 32 is connected to the tank 31 and the other end of the feeding pipe 32 is connected to the dispense head 35. Between one end and the other end of the feeding pipe 32, a valve 33 is provided.

When the valve 33 is opened, the interior space of the tank 31 is connected to the interior space of the dispense head 35, and the vapor deposition material 39 in the tank 31 moves to the dispense head 35. To the contrary, when the valve 33 is closed, the interior space of the tank 31 is shut off from the interior space of the dispense head 35 and the vapor deposition material 39 in the tank 31 no longer moves to the dispense head 35.

A pressure generator 36 is attached to the dispense head 35, and the pressure generator 36 is connected to a controller 37. When the controller 37 applies a drive voltage for driving the pressure generator 36 to the pressure generator 36, the pressure generator 36 applies a pressure to the vapor deposition material 39 inside the dispense head 35, and the vapor deposition material 39 inside the dispense head 35 is pushed out and dispensed as droplets from the dispense orifice 38.

When the drive voltage is not applied to the pressure generator 36, the vapor deposition material 39 does not leak out from the dispense orifice 38 and is held inside the dispense head 35.

As discussed above, each dispense orifice 38 faces the surface of the heating member 25; and therefore, the droplets of the vapor deposition material 39 dispensed from the dispense orifice 38 lands on the surface of the heating member 25. At this time, if the heating member 25 is heated to the evaporating temperature of the vapor deposition material 39 or higher, the vapor deposition material 39 that has landed thereon evaporates and vapor is generated.

The pipe 71 is connected to the evaporation chamber 21 of the vapor generator 20. When the switching device 70 is kept in the open state, the interior space of the evaporation chamber 21 is connected to the interior space of the discharge device 50 and the vapor generated in the evaporation chamber 21 moves to the discharge device 50 and is then discharged into the film formation chamber 11 from the discharge hole 55.

Next, a process for forming an organic thin film using the vapor deposition apparatus 10b is described.

The liquid vapor deposition material 39 is prepared by dissolving or dispersing an organic material in solvent (such as, a light-emitting organic material) as a main component (host) of which an additive (dopant) (such as, a coloring agent) is added. This vapor deposition material 39 is stored in the tank 31.

The vacuum evacuation system 9 is connected at least to the film formation chamber 11 and the tank 31, respectively. The valve 33 between the tank 31 and the dispense head 35 is closed; and in a state where the dispense head 35 is empty, the space above the liquid surface of the vapor deposition material 39 of the tank 31 is evacuated and the inside of the film formation chamber 11 is evacuated. Consequently, a vacuum ambience having a predetermined pressure (for example, 10⁻⁵ Pa) is formed in the space above the liquid surface of the vapor deposition material 39 inside the tank 31, inside the film formation chamber 11, inside the evaporation chamber 21, and inside the vapor transfer path from the evaporation chamber 21 to the discharge hole 55 (here, the discharge device 50, the switching device 70, and the pipe 71).

While the above-mentioned vacuum ambience is maintained, the heating member 25, the evaporation chamber 21, and the transfer path of vapor are heated with the heating means 48 to the heating temperature at which each component (organic material, solvent) of the vapor deposition material 39 can be evaporated (in the range of 250° C. or higher and 400° C. or lower).

When the vacuum evacuation system 9 is connected directly to the evaporation chamber 21 while the heating temperature is maintained, a valve 29 between the vacuum evacuation system 9 and the evaporation chamber 21 is closed; and after the evaporation chamber 21 is connected to the discharge device 50, the vapor deposition material 39 is dispensed to the heating member 25.

Inside the evaporation chamber 21, the vapor of the organic material and the vapor of the solvent, which are the components of the vapor deposition material 39, are generated, respectively. The evaporation chamber 21 and the transfer path of vapor are maintained at the above-mentioned heating temperature, so that the vapor generated in the evaporation chamber 21 is discharged from the discharge hole 55 without being deposited on the way.

Inside the film formation chamber 11, a substrate holder 15 is disposed. While the vacuum ambience is maintained, a substrate 81 is carried into the film formation chamber 11; and at least until vapor begins to be discharged from the discharge hole 55, the substrate holder 15 is made to hold the substrate 81 and the surface of the substrate 81 is kept facing the discharge hole 55 of the discharge device 50. The vapor of the organic material and the vapor of the solvent discharged from the discharge hole 55 reach the surface of the substrate 81.

The solvent used for the vapor deposition material 39 includes alcohol as its main component, the molecular weight of which is lower than the molecular weight of the organic material, and the vapor pressure of the solvent is higher than the vapor pressure of the organic material.

The temperature of the surface of the substrate 81 and the vacuum ambience inside the film formation chamber 11 are set such that, even when the organic material is deposited on the surface of the substrate 81, the vapor of the solvent is not deposited; and therefore, the solvent is not deposited on the surface of the substrate 81 but evacuated by the vacuum evacuation system 9. Thus, a thin film of organic material (organic thin film) is grown on the surface of the substrate 81.

The substrate 81 on which the film formation has been completed is removed from the substrate holder 15 and the new substrate 81 is carried into the film formation chamber 11 and attached to the substrate holder 15 (exchange of the substrates 81). After the exchange of the substrates 81, the vapor deposition material 39 is dispensed to the heating member 25; and thus, it is possible to form an organic thin film also on the new substrate 81. By repeating the exchange of the substrates 81 and the film formation of the organic thin film, it is possible to continuously form the organic thin film on the plurality of the substrates 81.

It may also be possible to evacuate the inside of the evaporation chamber 21 by the vacuum evacuation system 9 to remove residual vapor in the meantime from the completion of film formation to the start of the next film formation.

When the plurality of vapor generators 20 are connected to the discharge device 50 and the different vapor deposition materials 39 are stored in the vapor generators 20, respectively, it is possible to form two or more different kinds of organic thin film on the surface of the substrate 81. Specifically, after one organic thin film is formed, the evaporation chamber 21 in which film formation has been completed is shut off from the discharge device 50 while the substrate 81 is held by the substrate holder 15 without exchange of the substrates 81, and the evaporation chamber 21 of another vapor generator 20 is connected to the discharge device 50; and then, the vapor of the different vapor deposition materials is generated in the evaporation chamber 21.

For example, in order to form an organic thin film (colored layer) of three or more different colors, a mask is disposed between the substrate 81 and the discharge device 50; and after the film formation of a colored layer of one color is completed and before the film formation of the next colored layer is started, the positional relationship between the mask and the substrate 81 is changed; and thus, the colored layers of respective colors are formed in the different regions on the surface of the substrate 81.

If either one or both of the upper electrode and the lower electrode are patterned and set in a state such that a voltage can be applied to each colored layer, individually, it is possible to display an image or character in full color by applying a voltage to the colored layer of the selected color in the selected position to emit light therefrom.

Further, if the mask is not used, or the positional relationship between the mask and the substrate 81 is not changed, the colored layer of each color is stacked in the same position; and therefore, an organic EL element for white light emission can be obtained.

Although it is not limited in particular, the pressure generator 36 is, for example, a piezoelectric element or heating means.

When the pressure generator 36 is a piezoelectric element and if a drive voltage is applied, the piezoelectric element deforms and the vapor deposition material 39 is pushed out (piezoelectric method)

When the pressure generator 36 is a heating means and if a drive voltage is applied, the temperature of the heating means rises, the vapor deposition material 39 in the dispense head 35 is heated and bubbles are produced, and the bubbles push out the vapor deposition material 39 (thermal method).

The pressure generator 36 is arranged in the vicinity of each dispense orifice 38, respectively. The controller 37 is configured to be able to apply a voltage to the pressure generator 36, individually. The amount of the vapor deposition material 39 to be dispensed at a time from each dispense orifice 38 is small and it is possible to select one or more dispense orifice 38 in order to dispense the vapor deposition material 39 among the plurality of dispense orifices 38; and therefore, it is easy to control the amount of the vapor deposition material 39 to be disposed on the heating member 25.

If the height of the tank 31 is set to a height such that the vapor deposition material 39 in the dispense head 35 does not overflow from the dispense orifice 38 by the gravity force, the vapor deposition material 39 does not leak out from the dispense orifice 38 in a state such that no drive voltage is applied to the pressure generator 36.

The temperature of the dispense head 35 does not rise to a high temperature even when the evaporation chamber 21 and the heating member 25 are heated, but is maintained at a temperature less than the heating temperature (less than 240° C.); and therefore, the vapor deposition material 39 does not evaporate inside the dispense head 35. Thus, the vapor deposition material 39 in the dispense head 35 does not change in quality and the meniscus is not disturbed so that no dispense trouble will occur in the dispense head 35.

If either one or both of a heat insulating member 57 and a cooling means 49 are provided in the dispense chamber 41, the dispense head 35 becomes more difficult to be heated. The heat insulating member 57 is made of a heat insulating material, such as ceramic, for example, and is disposed between the dispense chamber 41 and the evaporation chamber 21 so that thermal conduction from the evaporation chamber 21 can be prevented.

The tank 31 is disposed apart from the evaporation chamber 21 outside the evaporation chamber 21 so that the tank 31 is not heated and the vapor deposition material 39 in the tank 31 does not deteriorate.

When the thickness of an organic thin film to be formed is determined in advance, a preliminary test is conducted by forming a film under the same condition as that of the actual film formation process before the actual film formation proceeds in order to obtain a relationship between the amount of the vapor deposition material 39 and the film thickness; and then, an amount of the vapor deposition material 39 required for forming a film with a film thickness predetermined from the acquired relationship is acquired.

The amount of the vapor deposition material 39 to be dispensed at a given time from the dispense orifice 38 is known. The dispense orifice 38 from which the vapor deposition material 39 is dispensed is selected and then, the number of dispense time is calculated by the number of the selected dispense orifice and the amount of dispense at one time for the selected dispense orifices 38 in order to equal the total amount of dispense to the necessary amount.

The time required to form one organic thin film is determined in advance. The number of dispense times of each of the selected dispense orifices 38 from the start of dispense until the film formation time elapses is set, in advance, to the number of times acquired. After the film formation time elapses and dispensing is performed at a number of times that is acquired in advance, the dispensing is terminated. The total amount of the vapor deposition material 39 dispensed to the heating member 25 is the amount required for forming a film with the predetermined film thickness; and therefore, the organic thin film grown on the surface of the substrate 81 has the predetermined film thickness.

If the number of dispense times from each dispense orifice 38 is set to a multiple number of times and the required amount of the vapor deposition material 39 is divided and fed in two or more times, the vapor deposition material 39 is not scattered on the heating member 25 because a large amount of the vapor deposition material 39 is not fed to the heating member 25 at a time. Further, if the dispense intervals from each dispense orifice 38 are set to the intervals to which the film formation rate is constant, the distribution of film thickness and film quality of the organic thin film are improved as compared to the case where the film formation rate fluctuates.

The heating method of the heating member 25 is not limited in particular. For example, it may also be possible to configure the heating member 25 by a high-resistance conductive material and the heating member 25 is inductively heated by forming an electromagnetic field inside the evaporation chamber 21.

Furthermore, it may also be possible to provide a window capable of transmitting laser light in the evaporation chamber 21 and to heat the heating member 25 by irradiating the surface of the heating member 25 with laser light from an external laser generator via the window.

If the surface (mount surface) of the heating member 25 that faces the dispense orifice 38 is inclined with respect to the horizontal plane, the droplet that has landed on the mount surface spreads on the mount surface; and therefore, the vapor deposition material 39 evaporates in a short time.

If the distance between the landing position of the droplet on the mount surface and the lower end of the heating member 25 is set such that the droplet that has landed thereon evaporates completely before it reaches the lower end of the heating member 25 when the heating member 25 is heated to the heating temperature, the vapor deposition material 39 evaporates without overflowing from the heating member 25.

Although the construction material of the heating member 25 is not limited in particular, those which have a high thermal conductivity (such as, metal, alloy, and inorganic material) are desirable. Among these, silicon carbide (SiC) is particularly desirable because it is excellent both in thermal conductivity and in mechanical strength.

The installation position of the vapor generator 20 is not limited in particular and it may also be possible to install part or the whole of the vapor generator 20 inside the same vacuum chamber 11 as the discharge device 50.

Although it may also be possible to integrate the evaporation chamber 21 and the film formation chamber into one unit and dispose the substrate 81 in the evaporation chamber 21 for performing film formation, the size of the film formation chamber 11 becomes larger compared to a case where the film formation chamber 11 and the evaporation chamber 21 are separated. Consequently, as shown in FIG. 2, it is desirable for the film formation chamber 11 and the evaporation chamber 21 to be separated and vapor generated in the evaporation chamber 21 to be introduced to the dispense device 50 so as to be discharged inside the film formation chamber 11.

If a gas feeding system is connected to the evaporation chamber 21 and vapor is generated while an inert gas (Ar, Ne, Xe, or the like.) is fed, the vapor is swept away by the inert gas; and therefore, the moving efficiency of vapor is improved.

Although the solvent used for the vapor deposition material 39 is not limited in particular, solvent including lower alcohol (the number of carbons is 1 to 6) as a main component are desirable in order to reduce the amount of residual solvent in the organic thin film. If the film quality of the organic thin film is not affected adversely, it is also possible to add a surfactant or the like to the vapor deposition material 39.

The vapor generator 20 and the vapor deposition apparatus 10 of the present invention can also be used for forming a film other than an organic thin film for an organic EL element.

1. A vapor deposition apparatus, comprising:
an evaporation chamber;
a feeding device that feeds a liquid vapor deposition material including an organic material into the evaporation chamber,
an discharge device which is connected to the evaporation chamber and to which vapor generated in the evaporation chamber is fed; and
a vacuum chamber where the vapor is discharged in an interior space of the vacuum chamber from the discharge device,
wherein the feeding device includes:
a tank in which the liquid vapor deposition material is disposed, and
a dispense head connected to the tank,
wherein the dispense head is provided with a dispense orifice,
wherein the vapor deposition material is fed from the tank to the dispense head and dispensed from the dispense orifice to an interior space of the evaporation chamber.

2. The vapor deposition apparatus according to claim 1, further comprising:
a heating member arranged inside the evaporation chamber; and
a heating means for heating the heating member,
wherein the vapor deposition material dispensed from the dispense orifice is disposed on the heating member.

3. (canceled)

4. The vapor deposition apparatus according to claim 1,
wherein the dispense head has a pressure generator that applies a pressure to the vapor deposition material inside the dispense head, and the vapor deposition material to which the pressure is applied is dispensed from the dispense orifice.

5. The vapor deposition apparatus according to claim 1, further comprising:
a heating device which heat the vapor deposition material to be its evaporating temperature or higher.

6. A method for forming an organic thin film, comprising the steps of:
disposing a liquid vapor deposition material including an organic material in a tank,
discharging the vapor deposition material from a dispense head connected to the tank into an evaporation chamber,
generating vapor by heating the vapor deposition material in the evaporation chamber, and
discharging the vapor from an discharge device connected to the evaporation chamber into an interior space of a vacuum chamber so as to form a thin film on a surface of an object to be film-formed positioned in the vacuum chamber.

7. The method for forming an organic thin film according to claim 6, the vapor generating step further comprising:
heating a heating member arranged in the evaporation chamber to an evaporating temperature of the vapor deposition material or higher, and
discharging the vapor deposition material from the dispense head to the heating member so as to generate the vapor.
